(19) United States
(12) Patent Application Publication
(10) Pub. No.: US 2012/0224346 A1
(43) Pub. Date: Sep. 6, 2012

(54) ARRANGEMENT WITH CHIP AND CARRIER

(76) Inventor: Leif BERGSTEDT, Varberg (SE)

(21) Appl. No.: 13/469,756

(22) Filed: May 11, 2012

Related U.S. Application Data
(63) Continuation of application No. PCT/CN2010/073354, filed on May 28, 2010.

(51) Int. Cl. H05K 7/06

(52) U.S. Cl. 361/783

(57) ABSTRACT

An apparatus includes chip and a carrier of the chip. A ridge is positioned between the chip and the carrier. The ridge is adapted to increase thermal contact between the chip and the carrier. The chip is attached to a contact surface on the carrier by an adhesive member.

### CROSS-REFERENCE TO RELATED APPLICATIONS

This application is a continuation of International Application No. PCT/CN2010/073354, filed on May 28, 2010, which is hereby incorporated by reference in its entirety.

### FIELD OF THE APPLICATION

The present invention relates to an arrangement comprising a chip and a carrier of the chip, where the chip can be attached to a contact surface on the carrier by means of an adhesive member. The present invention also relates to a chip in an inventive arrangement and to a carrier in an inventive arrangement.

### BACKGROUND OF THE APPLICATION

Power Amplifier chips (PA chip) are attached at their carriers mostly by some 20 to 100 μm silver epoxy adhesions. This is not ideal because the low thermal conductivity of silver epoxy adhesion, which normally is in the range of 7 to 65 Watt per meter Kelvin (centigrade) (Wm-1K-1) depending of type. This should be compared with 380 Wm-1K-1 for copper, 290 Wm-1K-1 for gold and 420 Wm-1K-1 for silver. One of the reasons for the thickness of the adhesion layer is because the chip “floats” on the adhesion.

The general way to solve the problem of increasing the thermal conductivity of the adhesion used to attach chips to a carrier is to increase the silver content in the adhesion, using thin silver flakes, and to have thin adhesion layers. However, increased silver content in the adhesion is also an increased cost and a decreased adhesive strength.

Through conventional adhesion technology two flat surfaces are attached to each other. This means that the chip “floats” on the adhesion depending of the viscosity of the adhesion. It is not possible to press down the chip too much because the chips are quite brittle and the surface might be sensitive because of air-bridges at the gate areas on the chip. Normally, a chip-tool that “grabs” the chip on the edges is used during the die-bonding.

The carrier can be made out of different materials, but many times the carrier for a PA chip is a silver plated copper sheet. The side of the chip facing the carrier is often plated with a thin layer of gold. This means that the two flat surfaces that are to be attached to each other are made out of materials with high thermal conductivity. The component on the chip is positioned at the side facing away from the carrier, and the chip material itself has a relatively bad thermal conductivity, such as 55 Wm-1K-1 for GaAs and 149 Wm-1K-1 for Silicon. For operating frequencies less than 60 GHz, chip thickness/height is commonly in the range of 100 μm. Parts of the component, such at the gate area of a PA, generates heat, which will form hot spots on the side of the chip facing the carrier.

### SUMMARY

In some embodiments of the present invention, a ridge is positioned between the chip and the carrier. The ridge is adapted to increase the thermal contact between the chip and the carrier. In some embodiments, the ridge is positioned at the location of a hot spot at the side of the chip that is facing the carrier. If the chip comprises several separate hot spots grouped together, the ridge may be positioned at the location of the group of hot spots of the chip. If the chip comprises several separate hot spots, the arrangement may include several ridges, and that one ridge is positioned at the location of each hot spot of the chip. The ridge can either be a part of the chip or of the carrier.

In some embodiments, if the ridge is a part of the chip, the ridge may be up-plated on the side of the chip that is facing carrier. This ridge can for instance be plated on the chip on wafer-level. In some other embodiments, if the ridge is a part of the carrier, the ridge may be up-plated on the contact surface of the carrier. In this case, the ridge may be adapted in size so that required thermal contact is provided to a hot spot on the chip with consideration taken to possible miss-alignment during the attachment of the chip to the carrier. If the ridge is a part of the carrier, and if the carrier is a silver plated copper sheet, the ridge may be introduced through pattern plating on the copper plate before the final silver plating.

Various heights of a ridge are possible, and a ridge on a carrier can for instance be formed by a pattern plating of approximately 20 μm and a silver plating with a thickness of approximately 5 μm.

Regardless of wether the ridge is part of the chip or the carrier, the height of the ridge may be smaller than the thickness of the adhesive member so that a thin adhesive film is formed between the ridge and the carrier or chip as the chip is attached to the carrier. In some embodiments, the height of the ridge is 1 to 2 μm smaller than the thickness of the adhesive member.

Since the ridge will provide an increased thermal contact between the chip and the carrier at the hot spots of the chip, the thermal conductivity requirements on the adhesive member are not as crucial anymore, which means that the adhesive member can be an epoxy adhesion without silver content, or a silver epoxy adhesion, but in this case it could be sufficient with a low silver content epoxy adhesion. It is also possible to use a low conductive adhesion as adhesive member. This will enable the use of a thinner adhesive layer with maintained adhesive strength and without the expenses of a high silver content.

The present invention may also be used with components that require good thermal contact with the carrier, such as a power amplifier chip (PA-chip), in which case the ridge could be positioned to provide a cooling of the gate areas of the chip.

The advantages may include that the invention can provide a better thermal conductivity between a chip and a carrier of the chip, especially in areas of the hot spots of the chip, thereby enabling a better cooling of components requiring good cooling conditions, such as PA chips.

The present invention can also have a lower requirement on the thermal conductivity of the adhesive member between the chip and the carrier, which can enable the use of less expensive adhesive members and, when there is no requirement of high silver content in the adhesive member, it is also possible to use a thinner adhesive member, and all of this with a maintained or even increased adhesive strength compared to what is known in the background art.

Examplary embodiments according to the invention require less power of compression for achieving good or excellent thermal contact compared to state of the art technology.

An example chip for 60-70 GHz (or higher) approximately having a thickness of 50 μm is cooled efficiently and has a reduced risk of breaking in the assembly process as compared to prior art technology.

### BRIEF DESCRIPTION OF THE DRAWINGS

An arrangement, a chip and a carrier according to the present invention will now be described in detail with reference to the accompanying drawings, in which:

FIG. 1 is a schematic illustration of a ridge positioned between the chip and the carrier, showing the ridge as a part of the chip according to one embodiment of the present invention;

FIG. 2 is a schematic illustration of several ridges being parts of the chip according to one embodiment of the present invention;

FIG. 3 is a schematic illustration of a ridge being a part of the carrier according to one embodiment of the present invention;

FIG. 4 is a schematic illustration of how a ridge can be plated to a carrier according to one embodiment of the present invention;

FIG. 5 is a schematic illustration of how a ridge can be dimensioned according to one embodiment of the present invention; and

FIG. 6 is a schematic illustration of several ridges being parts of the carrier according to one embodiment of the present invention.

### DETAILED DESCRIPTION OF THE EMBODIMENTS

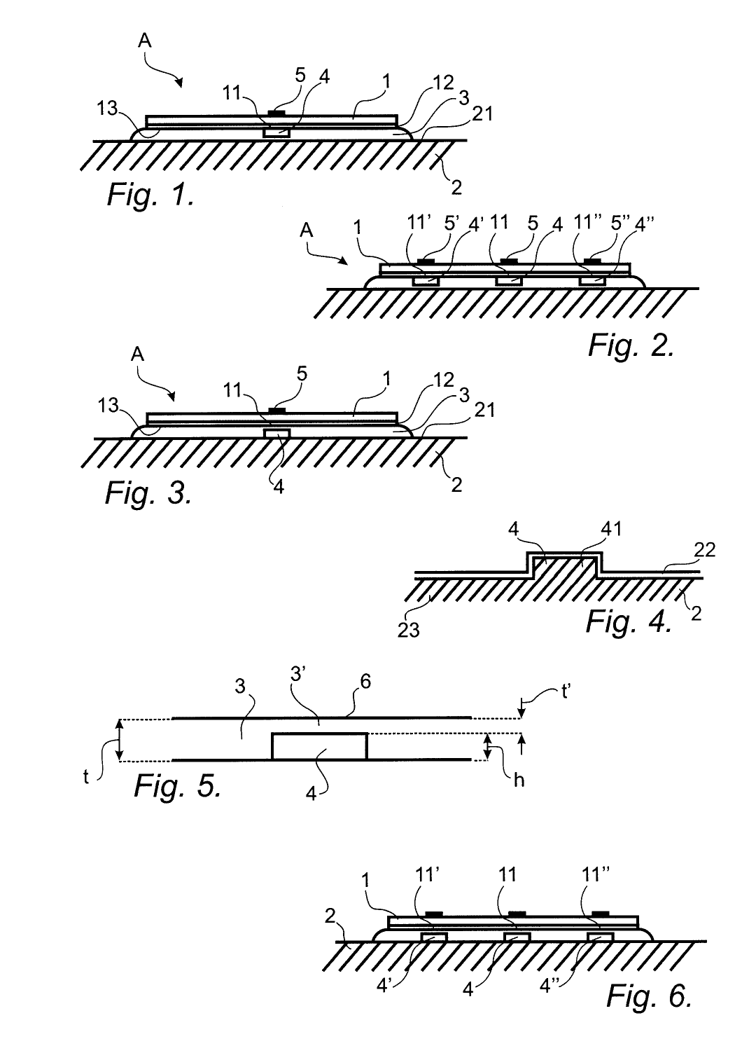

Embodiment of the present invention will now be described with reference to FIG. 1 showing an arrangement A comprising a chip 1 and a carrier 2 of the chip, where the chip 1 is adapted to be attached to a contact surface 21 on the carrier 2 by means of an adhesive member 3. The figure also shows a ground plate 12 belonging to the chip 1.

It should be understood that the figures are only simplified representations of the present invention where dimensions do not necessarily correspond to the dimensions of the real components.

According to some embodiments, a ridge 4 is positioned between the chip 1 and the carrier 2, which ridge 4 is adapted to increase the thermal contact between the chip 1 and the carrier 2. This increased thermal contact is achieved by the much smaller distance between the chip 1 and the carrier 2 in the area of the ridge 4 as the chip is attached to the carrier. Thus, despite physical contact surface being reduced, thermal conductivity can be increased due to quality of the thermal contacting.

According to some embodiments, the ridge 4 may be positioned at the location of a hot spot 11 at the side 13 of the chip that is facing the carrier. The hot spot 11 comes from a hot or warm part 5 of the component present in the chip 1.

FIG. 1 shows a hot spot and if the chip comprises several separate hot spots grouped together, then these would appear as one hot spot 11, and the ridge 4 would be positioned at the location of this group of hot spots appearing as one hot spot 11.

FIG. 2 shows an example where the chip 1 comprises several separate hot spots 11, 11′, 11″, due to several hot or warm parts 5, 5′, 5″ of the component, in which case, the arrangement A may include several ridges 4 4′, 4″, and that one ridge is positioned at the location of each hot spot of the chip 1.

FIGS. 1 and 2 shows an embodiment where the ridge 4, or ridges 4, 4′, 4″, is a part of the chip 1.

In this case, the ridge 4 may be up-plated on the side 13 of the chip 1 that is facing the carrier 2. One possible way of plating a ridge 4 to the chip 1 is to plate the ridge 4 on the chip 1 on wafer-level.

FIG. 3 shows an alternative embodiment where the ridge 4 is a part of the carrier 2. A ridge 4 on a carrier 2 can be made in different ways, and one proposed embodiment is that the ridge 4 is up-plated on the contact surface 21 of the carrier 2.

As a chip 1 is attached to the carrier 2, there is some uncertainty in the positioning of the chip to the carrier. In order to provide a good thermal contact for a chip which may be misaligned in the attachment anywhere within this uncertainty it is proposed that the ridge 4 is adapted in size so that required thermal contact is provided to a hot spot 11 on the chip 1 with consideration taken to the possible miss-alignment during the attachment of the chip 1 to the carrier 2.

FIG. 4 shows an example where the carrier 2 is a silver plated 22 copper sheet 23, in which case it is proposed that the ridge 4 is introduced through pattern plating 41 on the copper plate before the final silver plating 22.

In some embodiments, the size or height of the ridge is 25 μm, which in this case would be achieved if the thickness of the pattern plating is approximately 20 μm and the silver plating has a thickness of approximately 5 μm.

It is obvious that the ridge can be made with different heights, and FIG. 5 shows that regardless of if the ridge 4 is a part of the chip or of the carrier, and regardless of height, it is proposed that the height h of the ridge 4 is somewhat smaller than the thickness t of the adhesive member 3, allowing a thin part t′ of the adhesive member 3 to remain between the ridge 4 and the opposing part 6, the opposing part 6 being the carrier if the ridge is a part of the chip, and the opposing part 6 being the chip if the ridge is a part of the carrier. This means that the ridge 4 will not have mechanical contact with the opposing part 6, thereby limiting the risk of breaking the chip as it is attached to the carrier.

This remaining part 3′ of the adhesive member 3 can be of different thickness depending of requirements on thermal conductivity. If high thermal conductivity is required then it is possible to leave a very thin part 3′ of the adhesive member 3 between the ridge 4 and the opposing part 6, which would be the case if for instance the height of the ridge h is 1 to 2 μm smaller than the thickness t of the adhesive member 3.

According to some embodiments, the adhesive member 3 is an epoxy adhesion, and if required a silver epoxy adhesion, in which case it might be sufficient with a low silver content epoxy adhesion. The present invention allows the use of an adhesive member 3 that is a low conductive adhesion.

According to some embodiments, the present invention may be used with chips 1 whereupon there are components that require good cooling of its hot spots 11, such as a power amplifier chip (PA-chip), in which case the ridge can be positioned to provide a cooling of the gate areas of the chip. On a typical PA chip, the gate has an area of approximately 150×800 μm and the heat spread by the gate would generate a hot spot with an area of approximately 350×1000 μm. This means that a ridge 4 used to provide cooling of such hot spot would have the area of 350×1000 μm if positioned on the chip 1, however, if positioned on the carrier 2 the ridge 4 would be somewhat larger, for instance 500×1200 μm to also take possible misalignment of the chip 1 into consideration.

It should be understood that this is just an example and the skilled person realizes that the surface area and height of the ridge must be calculated and adapted to the specific implementation of the invention where the area of the ridge 4 depends on the area of the hot spot 11, which depends on the actual component on the chip 1, and the height h of the ridge 4 depends on the thickness t of the adhesive member 3.

With renewed reference to FIG. 1 it is shown that the present invention also relates to a chip 1 adapted to be attached to a contact surface 21 on a carrier 2 by means of an adhesive member 3.

The inventive chip 1 comprises a ridge 4 positioned on the side 13 facing the carrier 2, and the ridge 4 is adapted to increase the thermal contact between the chip 1 and the carrier 2.

In order to optimise the effect of this increased thermal contact it is proposed that the ridge 4 is positioned at the location of a hot spot 11 of the chip 1.

If the chip comprises several separate hot spots grouped together they can be seen as one hot spot 11, in which case it is proposed that the ridge 4 is positioned at the location of the group of hot spots 11 of the chip.

FIG. 2 shows that it is also possible that several different ridges 4, 4′, 4″ are used, and if the chip comprises several separate hot spots 11, 11′, 11″, then it is proposed that one ridge 4, 4′, 4″ is positioned at the location of each hot spot 11, 11′, 11″ of the chip 1.

The ridge can be made on the chip 1 in different ways, and one proposed way of making a ridge on the chip is that the ridge 4 is up-plated on the side 13 of the chip 1 that is adapted to face the carrier 2. It is possible to plate the ridge on the chip 1 on wafer-level.

As indicated in FIG. 5 it s proposed that the height h of the ridge 4 is somewhat smaller than the thickness t of used adhesive member 3, for instance it is possible to make the ridge so that the height of the ridge is 1 to 2 μm smaller than the thickness of used adhesive member, which will provide a very good thermal conductivity, even if the adhesive member would be a low conductive adhesion.

If the chip 1 has a component that requires good cooling, such as a power amplifier chip (PA-chip), then it is proposed that the ridge or ridges is/are positioned to provide a cooling of the gate areas of the chip.

With renewed reference to FIG. 3 it is shown that the present invention also relates to a carrier 2 adapted to provide a contact surface 21 for the attachment of a chip 1 by means of an adhesive member 3, which carrier 2 comprises a ridge 4 positioned on the contact surface 21, where the ridge 4 is adapted to increase the thermal contact between the carrier 2 and the chip 1.

According to some embodiments, the ridge 4 is positioned at a location where a hot spot 11 at the side 13 of the chip 1 that is facing the carrier 2 would be positioned as the chip 1 is attached to the carrier 2.

If the chip comprises several separate hot spots grouped together, then this can b seen as one hot spot 11 and the ridge 4 can be positioned at the carrier 2 on the location of the group of hot spots of the chip.

FIG. 6 shows that it is also possible that the chip 1 comprises several separate hot spots 11, 11′, 11″, in which case it is proposed that the carrier 2 comprises several ridges 4, 4′, 4″, and that one ridge is positioned at the location of each hot spot 11, 11′, 11″ of the chip 1.

As illustrated in FIG. 4, according to some embodiments, one way of making the ridge 4 on the carrier 2 is that the ridge 4 is up-plated 41 on the contact surface of the carrier 2.

It is proposed that the ridge 4 on the carrier 2 is adapted in size so that required thermal contact is provided to a hot spot 11 on the chip 1 with consideration taken to possible miss-alignment during the attachment of the chip 1 to the carrier 2.

If the carrier 2 is a silver plated copper sheet 23, then one possible way of introducing the ridge 4 is to pattern plate 41 the ridge 4 on the copper plate 23 before the final silver plating 22.

The thickness of the pattern plating can be approximately 20 μm, and that the silver plating can have a thickness of approximately 5 μm, which would provide a ridge with a height of approximately 25 μm.

FIG. 5 shows that regardless of height, it is proposed that the height h of the ridge 4 is somewhat smaller than the thickness t of used adhesive member 3. As an example, the height of the ridge can be 1 to 2 μm smaller than the thickness of the adhesive member.

It should be understood that the invention is not restricted to the aforedescribed and illustrated exemplifying embodiments thereof and that modifications can be made within the scope of the inventive concept as illustrated in the accompanying claims.

1. An apparatus comprising a chip and a carrier of said chip, where said chip is attached to a contact surface on said carrier by an adhesive member, wherein a ridge is positioned between said chip and said carrier, and said ridge is adapted to increase the thermal contact between said chip and said carrier.

2. An apparatus according to claim 1, wherein said ridge is positioned at a location of a hot spot at a side of said chip that is facing said carrier.

3. An apparatus according to claim 2, wherein said chip comprises several separate hot spots grouped together, and that said ridge is positioned at a location of said group of hot spots of said chip.

4. An apparatus according to claim 2, wherein said chip comprises several separate hot spots, and said apparatus comprises several ridges, and one ridge is positioned at a location of each hot spot of said chip.

5. An apparatus according to claim 1, wherein said ridge is a part of said chip.

6. An apparatus according to claim 5, wherein said ridge has been plated on said chip on a wafer level.

7. An apparatus according to claim 1, wherein said ridge is a part of said carrier.

8. An apparatus according to claim 7, wherein said ridge is up-plated on the contact surface of said carrier.

9. An apparatus according to claim 7, wherein said ridge is adapted in size to provide required thermal contact to a hot spot on said chip.

10. An apparatus according to claim 7, wherein said carrier includes a silver plated copper sheet, and said ridge is introduced through pattern plating on said copper plate before the final silver plating.

11. An apparatus according to claim 10, wherein a thickness of said pattern plating is approximately 20 μm and that said silver plating has a thickness of approximately 5 μm.

12. An apparatus according to claim 1, wherein the height of said ridge is smaller than the thickness of said adhesive member.

13. An apparatus according to claim 12, wherein the height of said ridge is 1 to 2 μm smaller than the thickness of said adhesive member.

14. An apparatus according to claim 1, wherein said chip is a power amplifier chip (PA-chip), and said ridge is positioned to provide a cooling of gate areas of said chip.

15. A chip adapted to be attached to a contact surface on a carrier by an adhesive member, wherein said chip comprises a ridge positioned on a side facing said carrier, and said ridge is adapted to increase a thermal contact between said chip and said carrier.

16. A chip according to claim 15, wherein said ridge is positioned at a location of a hot spot of said chip.

17. A chip according to claim 16, wherein said chip comprises several separate hot spots grouped together, and said ridge is positioned at a location of said group of hot spots of said chip.

18. A chip according to claim 16, wherein said chip comprises several separate hot spots, said chip comprises several ridges, and one ridge is positioned at the location of each hot spot of said chip.

19. A chip according to claim 15, wherein said ridge is up-plated on the side of said chip that is adapted to face said carrier.

20. A chip according to claim 15, wherein said ridge has been plated on said chip on a wafer level.

21. A chip according to claim 15, wherein a height of said ridge is 1 to 2 μm smaller than a thickness of said adhesive member.

22. A chip according to claim 15, wherein said chip is a power amplifier chip (PA-chip), and said ridge is positioned to provide a cooling of gate areas of said chip.

23. A carrier adapted to provide a contact surface for an attachment of a chip by an adhesive member, wherein said carrier comprises a ridge positioned on said contact surface, and said ridge is adapted to increase thermal contact between said carrier and said chip.

24. A carrier according to claim 23 wherein said ridge is positioned at a location of a hot spot at a side of said chip that is facing said carrier.

25. A carrier according to claim 23, wherein if said chip comprises several separate hot spots grouped together, and said ridge is positioned at a location of said group of hot spots of said chip.

26. A carrier according to claim 23, wherein if said chip comprises several separate hot spots, and said carrier comprises several ridges, and one ridge is positioned at a location of each hot spot of said chip.

27. A carrier according to claim 23, wherein said ridge is up-plated on the contact surface of said carrier.

28. A carrier according to claim 23, wherein said ridge is adapted in size to provice required thermal contact to a hot spot on said chip.

29. A carrier according to claim 23, wherein said carrier is a silver plated copper sheet, and said ridge is a pattern plating introduced on said copper plate before the silver plating.

30. A carrier according to claim 29, wherein a thickness of said pattern plating is approximately 20 μm, and said silver plating has a thickness of approximately 5 μm.

31. A carrier according to claim 23, wherein a a height of said ridge is 1 to 2 μm smaller than a thickness of said adhesive member.
